(19) United States
(12) Patent Application Publication
(10) Pub. No.: US 2001/0021567 A1
(43) Pub. Date: Sep. 13, 2001

(54) Method of forming device isolation structure

(75) Inventor: Toshifumi Takahashi, Tokyo (JP)

Correspondence Address: David A. Blumenthal, FOLEY & LARDNER, Washington Harbour, 3000 K Street, N.W., suite 500, Washington, DC, 20007-5109, US

(73) Assignee: NEC CORPORATION.

(21) Appl. No.: 09/801,906

(22) Filed: Mar. 9, 2001

(30) Foreign Application Priority Data
Mar. 10, 2000 (JP) 2000-67281

(51) Int. Cl. H01L 21/76

(52) U.S. Cl. 438/424

(57) ABSTRACT

The method of forming device isolation structures in semiconductor devices, according to the present invention, is comprised of a barrier layer formation step of forming predetermined isolation trenches on the primary surface of the semiconductor substrate, next oxidizing the surface of these isolation trenches so as to form an oxidized layer, and then depositing a oxidation stopping layer on top; an isolation trench filling step of depositing insulating material to the entire surface of the primary substrate surface so as to fill in the isolation trenches after the barrier layer formation step; and an annealing step of performing a wet oxidation process at a temperature higher than any of the processes after the isolation trench filling step forming the semiconductor device.

### BACKGROUND OF THE INVENTION

1. Field of the invention

The present invention generally relates to a method of manufacturing semiconductor devices. In particular, it relates to a method of forming a device isolation structure, which utilizes a shallow trench isolation structure (hereafter referred to as STI structure) to isolate devices.

2. Description of the Prior Art

Along with continuing advancements in the high integration of semiconductor devices, there are continued demands for not only the downsizing of the size of the devices, but also the downsizing of the size of the space between devices. One of the predominant techniques of device isolation, which scales down the size of the space between devices while maintaining a certain withstand voltage between devices, is involved in device isolating techniques using STI structures that have been energetically developed. The STI structure is configured by forming trenches having a specified depth between the devices needing to be isolated on the semiconductor substrate and then filling the trenches with an insulating material.

However, when STI structuring was utilized on silicon substrates, during oxidizing processes after the formation of the STI structure, oxygen was allowed to reach the silicon on the surface of the trench walls via the insulating material filling in the isolation trenches, and due to the oxidation of the silicon within the trenches progressing and increasing its volume, causing the resulting stress to be added to the silicon area bending the silicon grid. This develops problems such as defects in the formof dislocations possibly being induced within the substrate. If defects due to stress develop, then during later steps they may develop defects in the junction region causing electric current to leak, and triggering a deterioration in the operating characteristics of the transistors and the like.

Methods for solving the above problems have been devised, for example as disclosed in Japanese Patent Applications Laid-open No. Hei 8-46029, Hei 9-181163 and 2000-12677, which call for the formation of an oxidation stopping layer from a silicon nitride film (hereafter referred to as oxidation stopping nitride layer), silicon oxynitride film, or a multi-layered film combining them, before filling the trenches with the insulating material.

However, in the case where an oxidation stopping nitride layer is used, when the pad nitride layer that was used for forming the isolation trenches is removed, as shown in FIG. 26, problems developed such as the oxidation stopping nitride layer 320 in the boundary areas of isolation trench region 12 and device region 21 on the surface of the substrate being over-etched and becoming like area R; then during a later step of nitride layer etching becoming larger, and as shown in FIG. 27, developing indentations 335. When these sorts of indentations 335 develop, during a later, for example, gate electrode formation step, the gate electrode material remains in indentations 335 failing to be etched off, whichmakes it easier for defective shorts to develop between adjacent gate transistors, as shown by area P in FIG. 2, which is a top view of the devices. In addition, the concentration of electric fields from the gate electrodes formed at the ends of the device region makes it easier for hump characteristics to develop.

In Japanese Patent Application Laid-open No. Hei 8-46029, a method is disclosed in which the thickness of oxidation stopping nitride layer 320 is made to be less than 5 nm in order to suppress development of these indentations 335.

Furthermore, in Japanese Patent Application Laid-open No. Hei 9-181163, a manufacturing method is disclosed in which, as shown in FIG. 28, in order to suppress the hump characteristics of transistors, the deposited silicon nitride layer 402 on top of pad oxide layer 401 in the isolation trench formation region is removed forming openings 411, 412, and 413, and these openings 411, 412, and 413 are LOCOS (local oxidation of silicon) oxidized. These LOCOS oxidized layers 405 are next removed, and sidewalls 26, which are comprised of silicon or nitride silicon, are formed in openings 411, 412, and 413 within the isolation trench formation region; and afterwards the silicon substrate is selectivelyetched forming isolation trenches so that the corners of the isolation trenches and the boundary areas in the active zone where the devices are formed are rounded.

In Japanese Patent Application Laid-open No. 2000-12677, a method is disclosed, which suppresses development of indentations 335 in the edge of isolation trenches when removing the first oxidation stopping layer even if the oxidation stopping nitride layer is thick. This is accomplished through the formation of isolation trenches by making openings in the first oxidation stopping layer on top of the isolation trench formation region (corresponding to the pad nitride layer) and then forming sidewalls on the sides on the inner walls of these openings.

However, the conventional STI structure formation methods mentioned above hardly take into consideration operational deficienciesofthedevices, suchasincreasedelectricalcurrent leakage, due to defects that develop resulting from heat stress applied during later STI structure formation.

For this reason, in cases where the STI structure has been adopted for semiconductor memory devices such as SRAM or DRAM, it has been found that the percentage of defective memory cells compared to the total number of memory cells is relatively high. According to the results of testing performed by the inventor, there were problems such as the percentage of defective memory cells ranging from approximately 10% to 50%. Therefore, there were instances where recovery could not be accomplished by the redundant circuits, and the overall yield of the finished product being relatively low.

Furthermore, according to the manufacturing process disclosed in Japanese Patent Application Laid-open No. Hei 9-181163, the results obtained showed that the hump characteristics of the transistor could be suppressed; however, since the LOCOS oxidation processing is performed after openings are formed in the isolation trench formation region, as shown by area S in FIG. 28A, the eating into the LOCOS oxidation layer throughout device regions 21 and 22 cannot be avoided, and since it is difficult to control the amount d that has been eaten into, there are problems such as a decrease in the precision with which the devices are sized.

### BRIEF SUMMARY OF THE INVENTION

### Objectives of the Invention

The present invention aims to provide a method of forming STI structured device isolation structures, which can reduce deficiencies developing as a result of crystal defects, and suppress hump characteristics in transistors, while maintaining accuracy in the device length.

### Summary of the Invention

The method of forming device isolation structures in semiconductor devices, according to the present invention, is comprised of

a barrier layer formation step of forming predetermined isolation trenches on the primary surface of the semiconductor substrate, next oxidizing the surface of these isolation trenches so as to form an oxidized layer, and then depositing a oxidation stopping layer on top;

an isolation trench filling step of depositing insulating material to the entire surface of the primary substrate surface so as to fill in the isolation trenches after the barrier layer formation step; and

an annealing step of performing a wet oxidation process at a temperature higher than any of the processes after the isolation trench filling step forming the semiconductor device.

### BRIEF DESCRIPTION OF THE DRAWINGS

The above-mentioned and other objects, features and advantages of this invention will become more apparent by referencing the following detailed description of the invention taken in conjunction with the accompanying drawings, wherein:

FIG. 1 is a flowchart showing a synopsis of each step in the method of forming device isolation structures according to the first embodiment of the present invention;

FIG. 2 is a layered top view of an example of a MOS transistor included in a semiconductor device having the device isolation structures of the present invention;

FIG. 3 is a procedural cross-sectional view showing the layered cross section cut along line X to X′ of the main step of the first embodiment shown in FIG. 2;

FIG. 4 is a procedural cross-sectional view showing a main step of the first embodiment;

FIG. 5 is a procedural cross-sectional view showing a main step of the first embodiment;

FIG. 6 is a procedural cross-sectional view showing a main step of the first embodiment;

FIG. 7 is a procedural cross-sectional view showing a main step of the first embodiment;

FIG. 8 is a procedural cross-sectional view showing a main step of the first embodiment;

FIG. 9 is a procedural cross-sectional view showing a main step of the first embodiment;

FIG. l0 is a procedural cross-sectional view showing a main step of the first embodiment;

FIG. 11 is a procedural cross-sectional view showing a main step of the first embodiment;

FIG. 12 is a procedural cross-sectional view showing a main step of the first embodiment;

FIG. 13 is a procedural cross-sectional view showing a main step of the first embodiment;

FIG. 14 is a flowchart showing a synopsis of each step in the method of forming device isolation structures according to the second embodiment of the present invention;

FIG. 15 is a procedural cross-sectional view showing a main step of the second embodiment;

FIG. 16 is a procedural cross-sectional view showing a main step of the second embodiment;

FIG. 17 is a procedural cross-sectional view showing a main step of the second embodiment;

FIG. 18 is aprocedural cross-sectional view showing amain step of the second embodiment;

FIG. 19 is a procedural cross-sectional view showing a main step of the second embodiment;

FIG. 20 is a procedural cross-sectional view showing a main step of the second embodiment;

FIG. 21 is a procedural cross-sectional view showing a main step of the second embodiment;

FIG. 22 is a procedural cross-sectional view showing a main step of the second embodiment;

FIG. 23 is a procedural cross-sectional view showing a main step of the second embodiment;

FIG. 24 is a layered cross-sectional view cut along line Y to Y′ in FIG. 2 after the STI structure and then gate electrodes have been formed, according to the method of the second embodiment;

FIG. 25 is a layered cross-sectional view cut along line Y to Y′ in FIG. 2 after the STI structure and then gate electrodes have been formed without performing the first substrate etching step in the method of the second embodiment;

FIG. 26 is a layered cross-sectional view shown in order to describe the problems with conventional techniques;

FIG. 27 is a layered cross-sectional view that is shown in order to describe problems with conventional techniques;

FIGS. 28A and 28B are layered cross-sectional views that are shown in order to describe problems with the method disclosed in Japanese Patent Application Laid-open No. Hei 9-181163; and

FIG. 29 is a graph of the testing results showing the effects of certain wet oxidation process temperatures.

### DETAILED DESCRIPTION OF THE INVENTION

In the following, the preferred embodiments of the present invention will be described while referencing the attached FIGS. In the description of the drawings, identical devices are assigned the same reference numerals, and the overlapping descriptions are omitted.

### (First Embodiment)

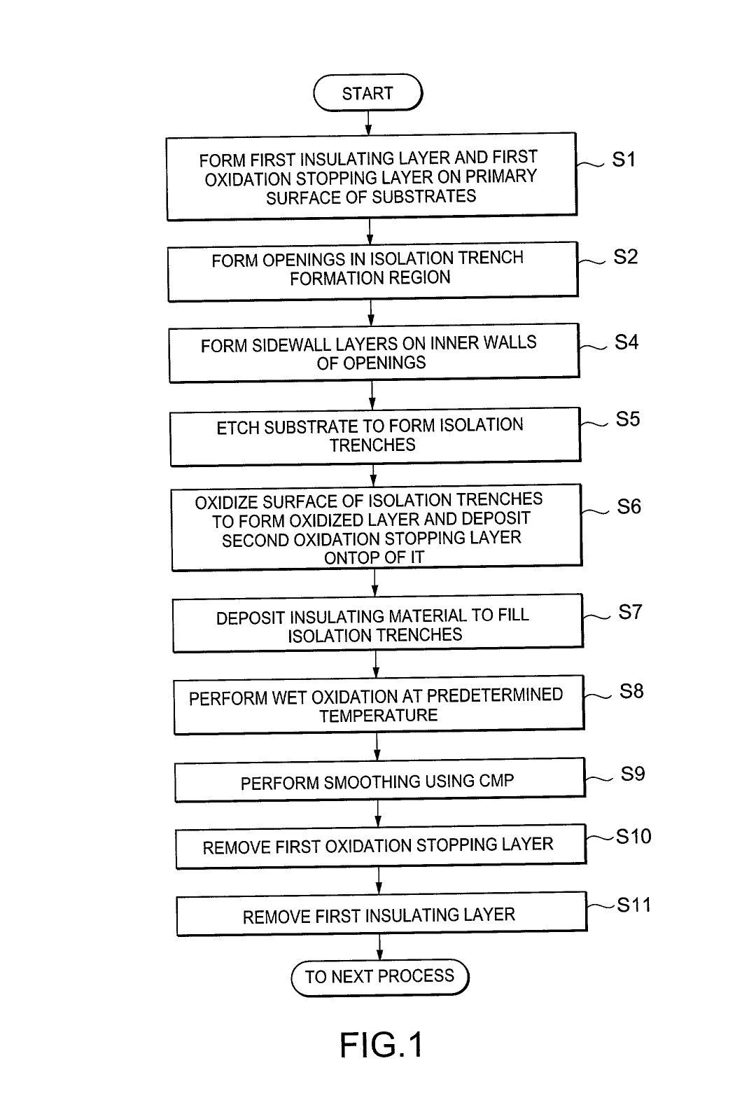

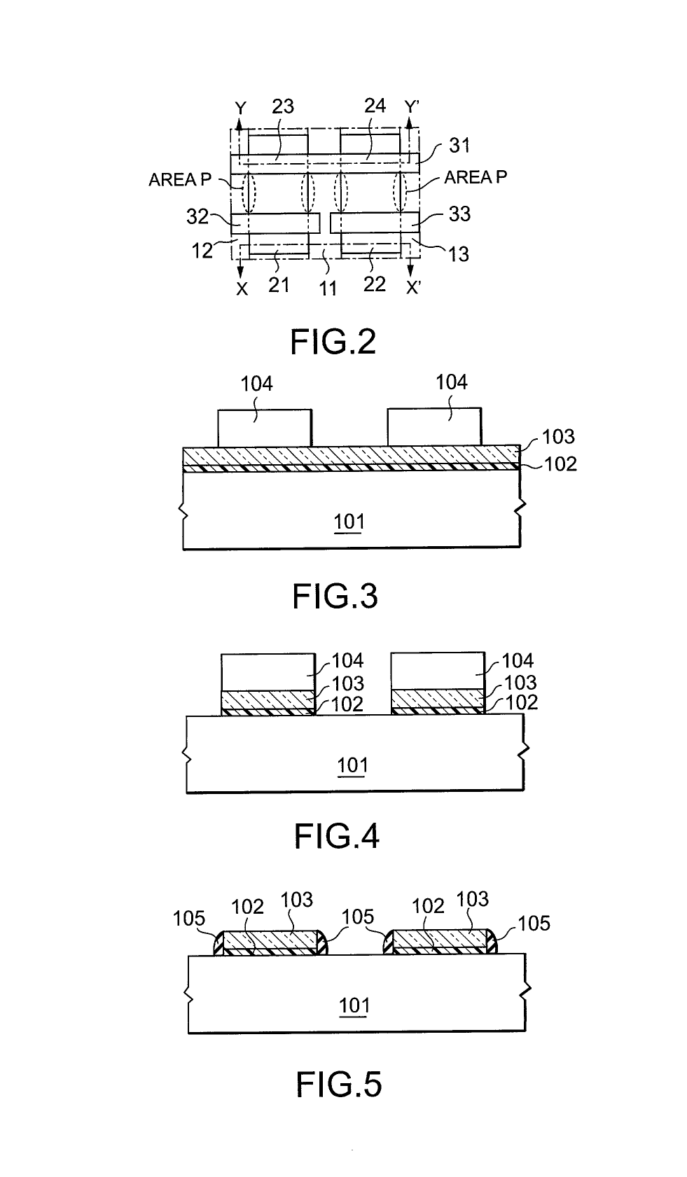

FIG. 1 is a flowchart showing a synopsis of each step in the method of forming device isolation trench structures according to the first embodiment of the present invention. FIG. 2 is a layered top view of an example of a MOS transistor, which is included ina semiconductor device having the device isolation structures of the present invention, and which includes device regions 21 and 22, isolation trenches 11, 12 and 13, gate electrodes 31, 32, and 33, and channel regions 23 and 24 in the lower part of gate electrode 31. FIGS. 3 to 13 are procedural cross-sectional views showing the layered cross sections of the main steps of this embodiment cut along line X to X′ in FIG. 2.

As shown in FIG. 1, the method of forming device isolation structures according to this embodiment is comprised of at least a barrier layer formation step S6, in which, after the formation of predetermined isolation trenches in the primary surface of the semiconductor substrate, the surfaces of these isolation trenches are oxidized to form an oxidized layer, and on them an oxidization stopping layer is deposited;

an isolation trench filling step S7, in which, after this barrier layer forming step, insulating material is deposited on the entire substrate surface filling in the isolation trenches; and

an annealing step S8, in which a wet oxidation process is performed at a temperature higher than any of the processes after the isolation trench filling step, which form the semiconductor device.

Next, the operation of this embodiment will be described while referencing FIGS. 1 to 13, which illustrate an example of the case where a silicon substrate (hereafter referred to as the Si substrate) is used as the semiconductor substrate.

To begin with, the principle surface of the Si substrate is oxidized to form an approximately 15 nm thick first silicon oxide layer 102 (hereafter referred to as the SiO layer), and on it first silicon nitride layer (hereafter referred to as the SiN layer) 103, which will become the etching mask, is deposited with a thickness of approximately 150 nm using, for example, plasma chemical vapor deposition (CVD) . In addition, on this first SiN layer 103, photo resist (hereafter referred to as PR) 104 is applied, and using lithographic techniques familiar to those skilled in the art, PR 104 on the regions where isolation trenches will be formed is removed. (FIG. 3)

Next, the first SiN layer 103 and the first SiO layer 102 are selectively etched off using anisotropic etching to form openings exposing the surface of the Si substrate. (FIG. 4)

Next, PR 104 is removed, and after a second SiO layer with a thickness of 10 to 30 nm has been deposited on the entire primary surface of the Si substrate (not shown in the FIGS.), this primary surface is subjected to anisotropic etching to remove the second SiO layer on the first SiN layer 103 which covers device regions 21 and 22, forming sidewall layers 105 on the side walls of the openings. (FIG. 5)

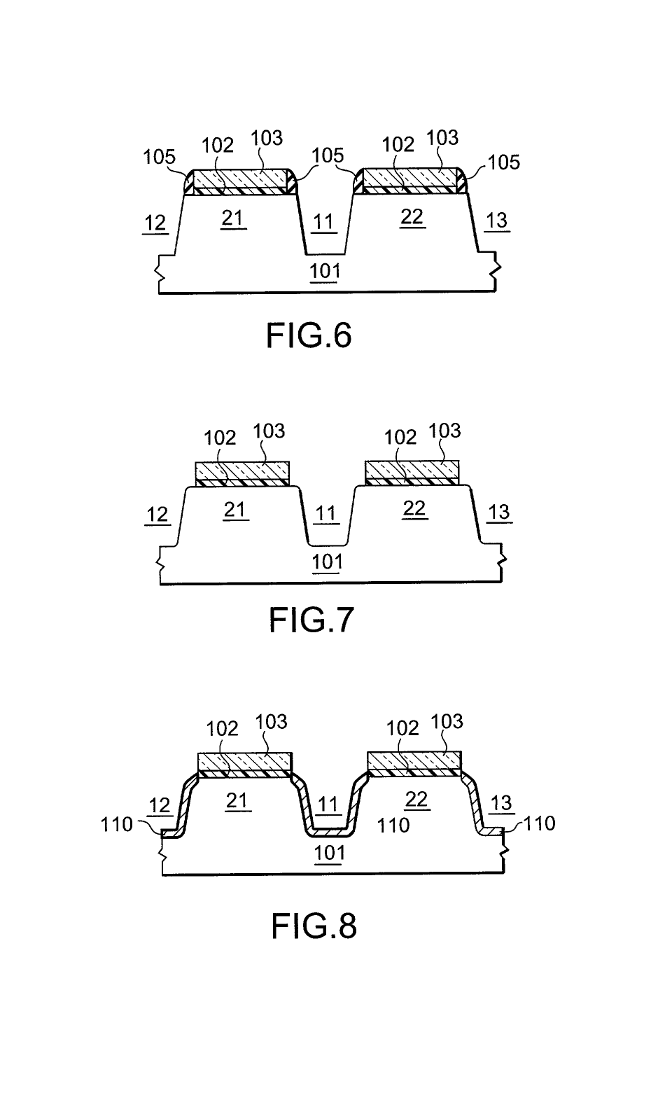

Next, after the exposed silicon inside the openings has been etched approximately 200 to 400 nm using first SiN layers 103 and sidewall layers as an etching mask (FIG. 6), sidewall layers 105 are etched off, forming isolation trenches 11, 12, and 13. (FIG. 7)

Next, in barrier layer formation step S6, after the exposed silicon surface in isolation trenches 11, 12, and 13 is oxidized in an O₂ atmosphere to form the third SiO layer 110 with a thickness of 10 to 20 nm (FIG. 8), the second SiN layer 120, which will become the oxidation stopping layer, is deposited on the entire primary surface of Si substrate 101 to form a thickness of 5 to 10 nm.

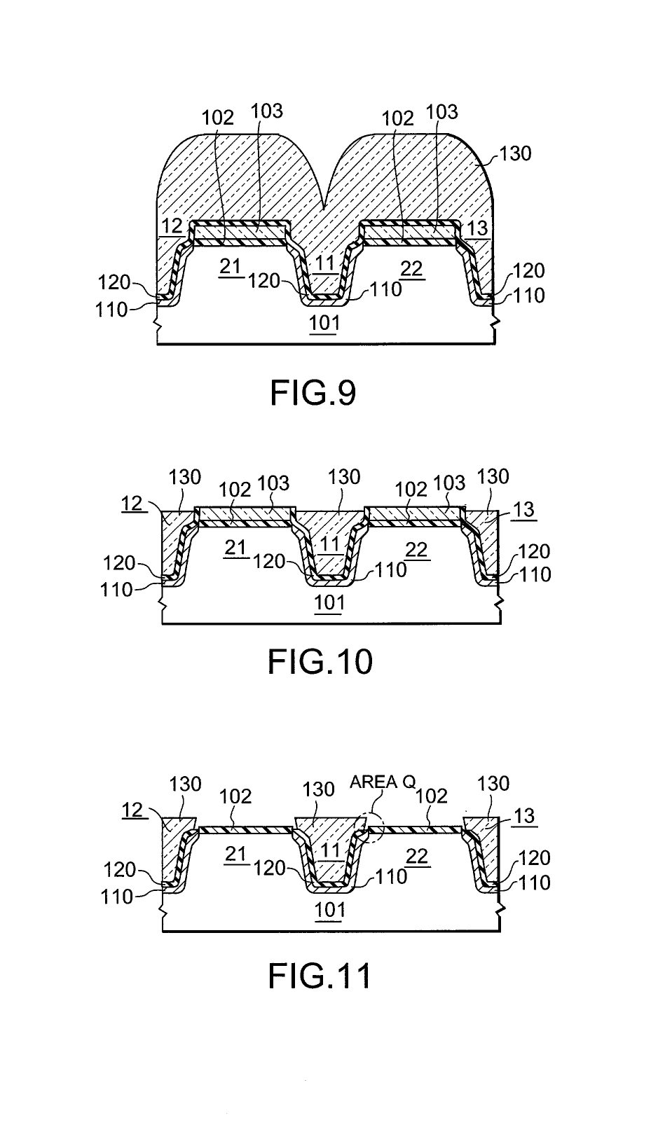

Next, in isolation trench filling step S7, the fourth SiO layer 130, which is comprised of an insulating material and which will fill in isolation trenches 11, 12, and 13 throughout the entire primary surface of Si substrate 101, is deposited by CVD using, for example, tetraethylortosilicate (TEOS) to form a thickness of approximately 400 to 700 nm. Thereafter, in annealing step S8, it is subjected to wet oxidation processing for about 5 minutes at a temperature (here it is assumed to be 1100° C.) that is at least as high as the heat processing temperature to which Si substrate 101 is subjected during a later process. (FIG. 9)

Next, using chemical mechanical polishing (CMP), the fourth SiO layer 130, which acts as a stopping layer for the first SiN layer 103, which in turn covers device regions 21 and 22, is polished off to expose the first SiN layer 103. (FIG. 10)

Next, the first SiN layer 103 is removed by wet etching using, for example, hot phosphoric acid. At the same time as this, the nearby surfaces of the second SiN layer 120 are also subjected to etching. (FIG. 11)

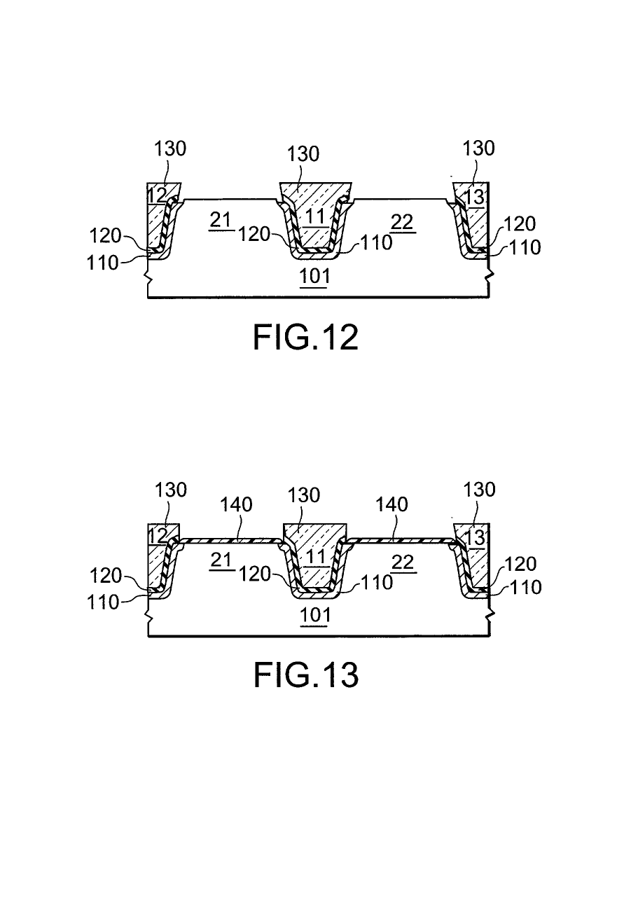

Next, wet etching is used to remove the first SiO layer 102 exposing device regions 21 and 22 in the Si substrate surface. (FIG. 12)

Next, the Si substrate surface of these exposed device regions 21 and 22 is subjected to a predetermined amount of oxidation forming a sacrificial oxidized layer (not shown in the FIGS.), and after this sacrificial oxidized layer is removed, the fifth SiO layer 140, which will become the gate insulating layer, is formed to be a certain predetermined thickness.

Hereafter, the desired devices are formed in these device regions 21 and 22 using device formation methods and wiring methods familiar to those skilled in the art. Since the wiring will then complete the semiconductor device formation, the respective descriptions of these methods are omitted.

With this embodiment, after sidewall layers 105 are configured before etching the substrate to form the isolation trenches, and also after the isolation trenches 11, 12 and 13 are filled in with fourth SiO layer 130, a wet oxidation process is performed for about five minutes at 1100° C., which is higher than the heat processing temperature to which this Si substrate 101 will be subjected to in a later process, in annealing step S8. As a result, since part of the second SiN layer 120, which is the oxidation stopping layer, is oxidized to become SiON at the same time as the fourth SiO layer 130 undergoes high densification, it is possible to limit the occurrence of defects in device regions 21 and 22 due to heat treatments (gate oxidation, activation treatment of ion implantation, etc.) in later steps, as well as limit the over etching (area Q of FIG. 1) of second SiN layer 120 at the upper edge of isolation trenches 11, 12 and 13 when removing the first SiN layer 130 using wet etching.

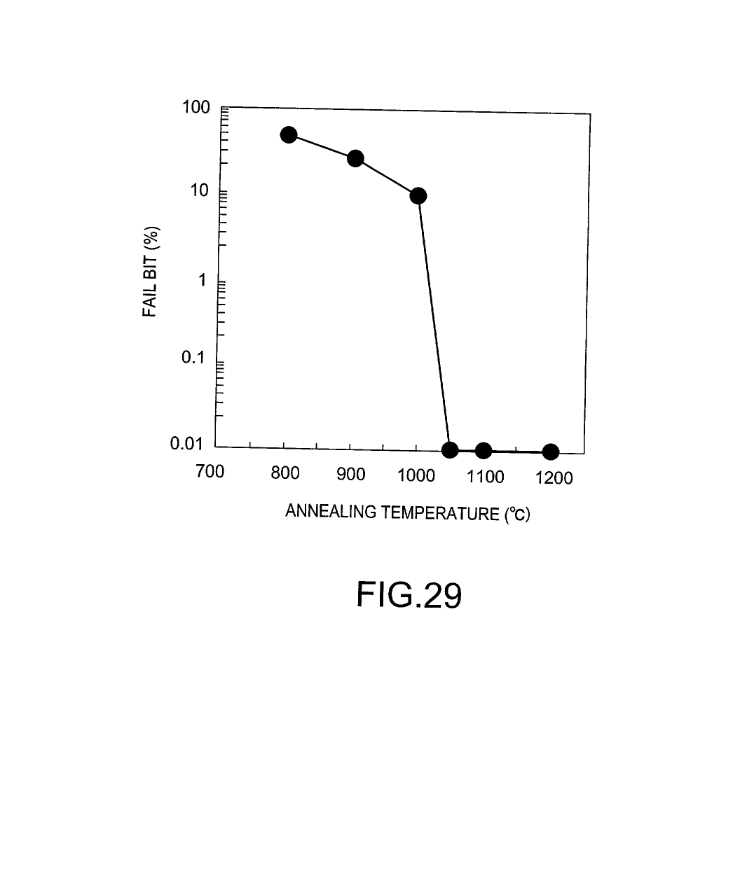

FIG. 29 is a graph showing the results of testing done by the inventor on the relationship between the annealing temperature and the rate of defective bits in a semiconductor device containing SRAM cells that utilize STI structuring, with the horizontal axis being the annealing temperature after filling the isolation trenches with insulating material and the vertical axis being the rate of defective bits developing in the finished product that are thought to be the result of crystal defects. As it is shown in this graph, performing annealing at a sufficiently high temperature above 1050° C. after the isolation trenches have been filled with insulating material allows for controlling development of defective devices during heat processes performed in steps after STI structure formation. Therefore, overall product yield can be improved by great margins.

As it has been described above, by performing wet oxidation processes at 1050° C. or higher, without increasing the number of steps, two results can be reached at the same time.

Moreover, the results of testing performed by the inventor confirm that the rate of defective cells developing can be reduced. In this case, part of the second SiN layer 120 is not oxidized but is kept as the SiN layer.

### (Second Embodiment)

The isolation trench formation method according to the second embodiment of the present invention will now be described.

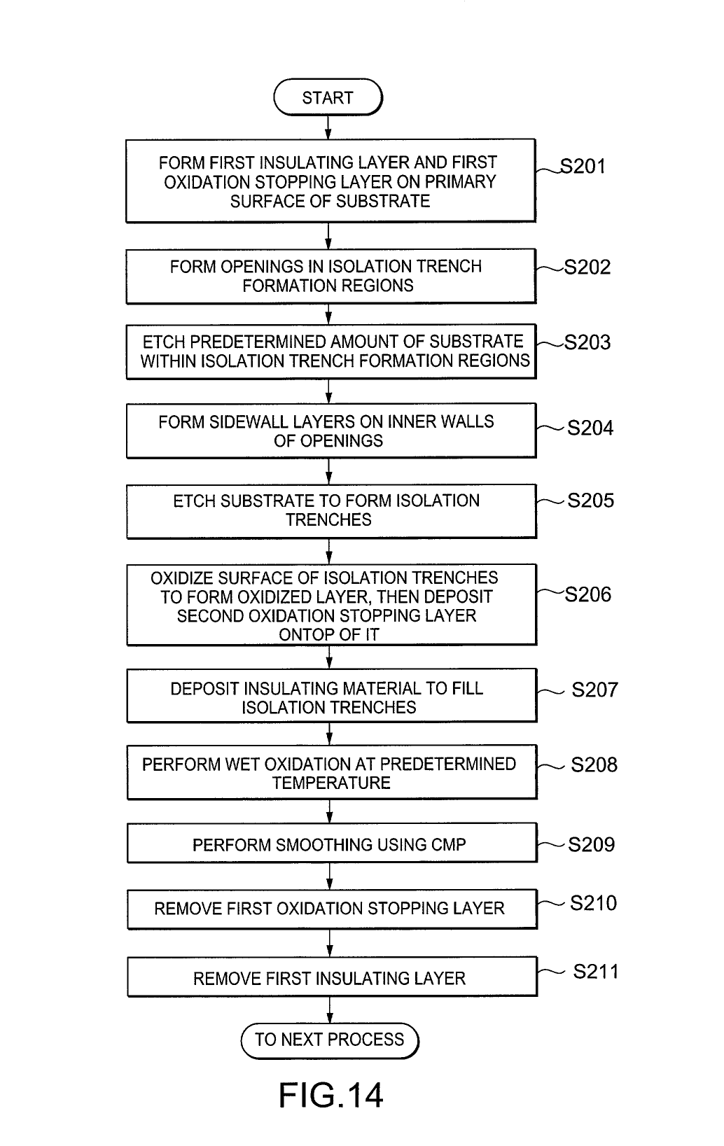

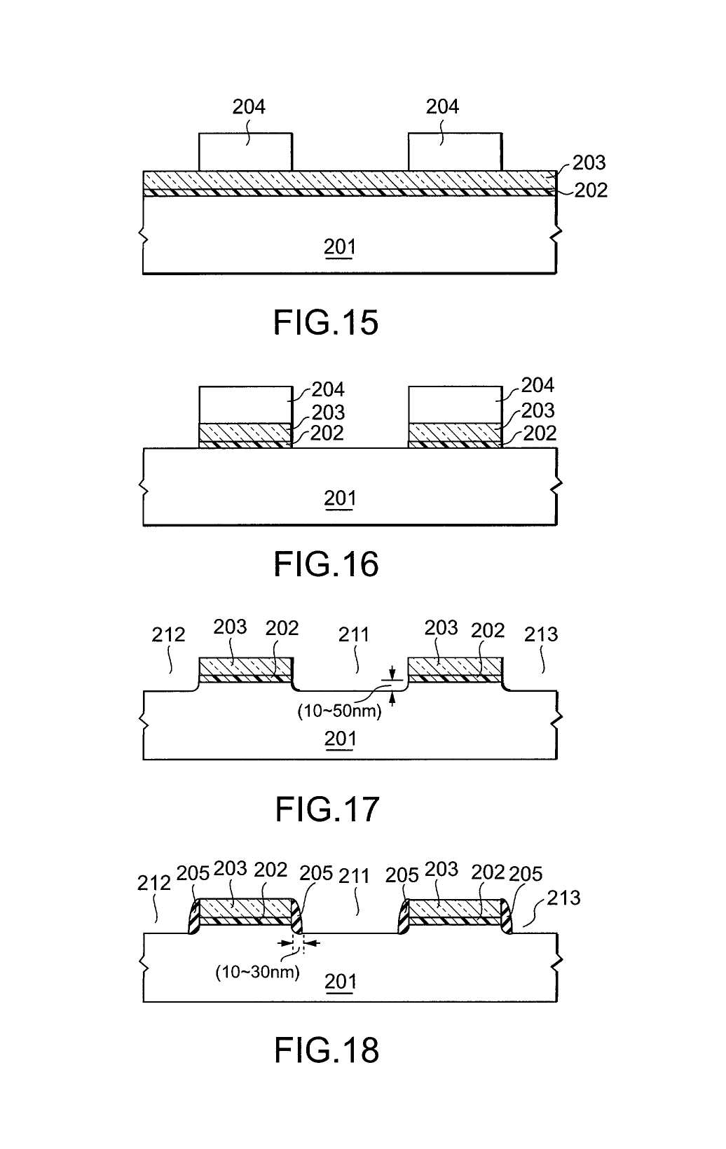

FIG. 14 is a flowchart showing a synopsis of each step in the method of forming device isolation structures according to the second embodiment of the present invention. FIGS. 15 to 23 are procedural cross-sectional views showing layered cross-sections cut along line X to X′ in FIG. 2 of the main steps of the second embodiment.

As shown in FIG. 14, the method of forming device isolation structures of this embodiment is comprised of at least a pad layer formation step S201, which forms on the primary surface of the semiconductor substrate, a first insulating layer and a first oxidation stopping layer in that order from the bottom layer;

pad layer opening formation step S202, which removes the first insulating layer and the first oxidation stopping layer from above the isolation trench formation region to form openings and expose the substrate;

first substrate etching step S203, which etches the substrate that has been exposed in the openings a certain predetermined amount;

sidewall formation step S204, which forms sidewall layers on the sidewalls of the openings after the first substrate etching step S203; and

second substrate etching step S205, which etches the substrate a certain predetermined amount forming isolation trenches after sidewall formation step S204.

Next, the operation of this embodiment will be described while referencing FIGS. 15 to 23, which show the example of a Si substrate being used as the semiconductor substrate.

To begin with, during pad layer formation step S201, the primary surface of Si substrate is oxidized forming first SiO layer 202, which will become the first insulating layer, to have a thickness of approximately 15 nm, then on it the first SiN layer 203, which will become the first oxidation stopping layer, is deposited using, for example, plasma CVD to have a thickness of approximately 150 nm. In addition, on this first SiN layer 203, PR 204 is applied and using lithographic techniques familiar to those skilled in the art, PR 204 on the regions where isolation trenches will be formed is removed. (FIG. 15)

Next, in pad layer opening formation step S202, the first SiN layer 203 and the first SiO layer 202 on the isolation trench formation regions where PR 204 has been removed are subjected to anisotropic etching, forming openings 211, 212, and 213, and exposing the surface of the Si substrate. (FIG. 16)

Next, in first substrate etching step S203, Si substrate 201, which is exposed inside openings 211, 212, and 213, is etched approximately 20 nm and PR 204 is removed. (FIG. 17)

Next, in sidewall formation step S204, after second SiO layer is deposited having a thickness of 10 to 30 nmon the entire primary surface of Si substrate 201 (not shown in the FIGS.), this entire primary surface is subjected to an anisotropic etching removing the second SiO layer from the first SiN layer 203, which covers the area above device regions 21 and 22, and forming sidewall layers 205 on the sidewalls of openings 211, 212, and 213. (FIG. 18)

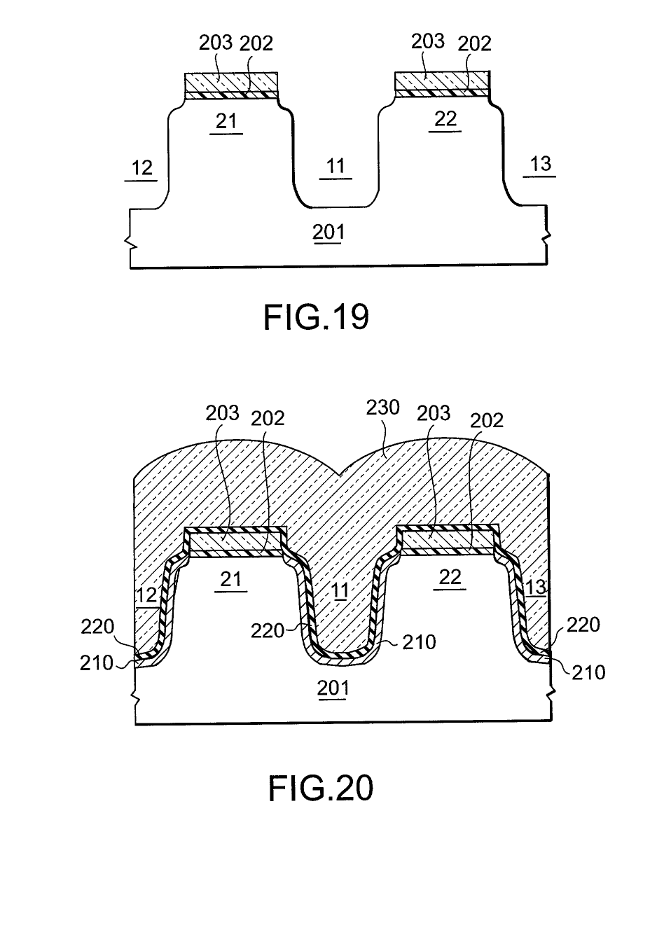

Next, in second substrate etching step S205, after sections of Si substrate 201 that are exposed in the openings 211, 212, and 213 are etched approximately 200 to 400 nm using sidewall layers 205 and the first SiN layer 203 as an etching mask, sidewall layers 205 are etched off forming isolation trenches 11, 12, and 13. (FIG. 19)

Hereafter, in the same manner as with the first embodiment, after the exposed silicon surface in isolation trenches 11, 12, and 13 is oxidized in an 02 atmosphere to form third SiO layer 210 with a thickness of 10 to 20 nm, the second SiN layer 220, which will become the oxidation stopping layer, is deposited on the entire primary surface of Si substrate 201 to form a thickness of 5 to 10 nm.

Next, after the fourth SiO layer 230, which is comprised of an insulating material and which will fill in isolation trenches 11, 12, and 13 throughout the entire primary surface of Si substrate 201, has been deposited by CVD using, for example, tetraethylortosilicate (TEOS) to form a thickness of approximately 400 to 700 nm, it is subjected to wet oxidation processing for about 5 minute sat a temperature (here it is assumed to be 1100° C.) which is at least higher than the heat processing temperature to which Si substrate 201 is subjected during a later process. (FIG. 20)

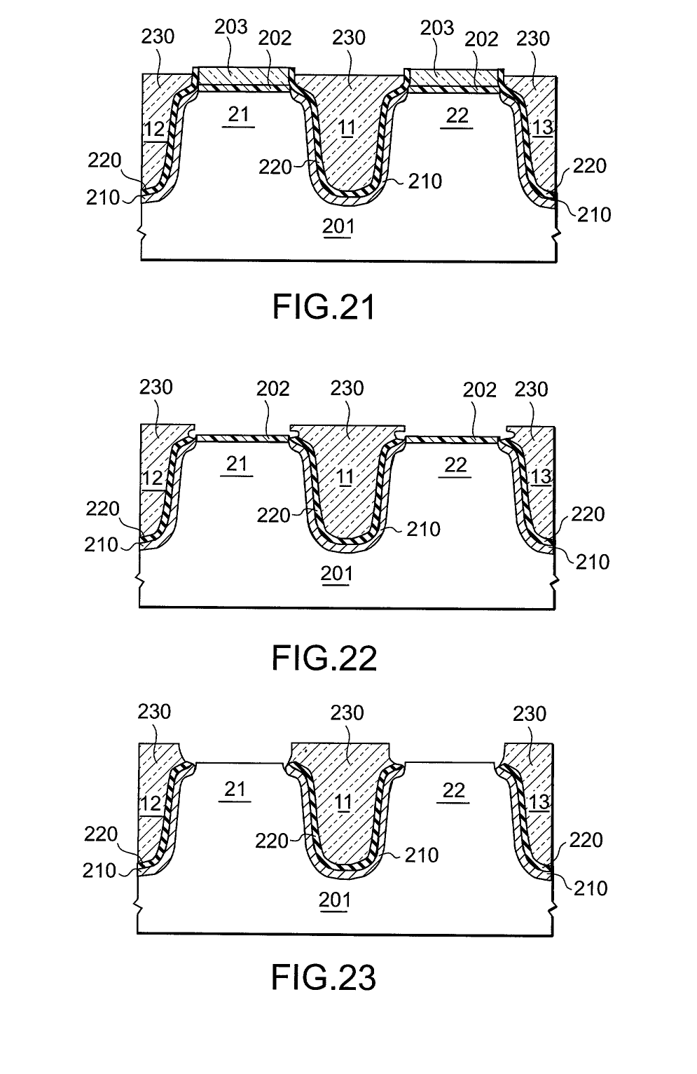

Next, using chemical mechanical polishing (CMP), the fourth SiO layer 230, which acts as a stopping layer for the first SiN layer 203, which in turn covers device regions 21 and 22, is polished off to expose the first SiN layer 203. (FIG. 21)

Next, first SiN layer 203 and the nearby surfaces of second SiN layer 220 are removed by wet etching using, for example, hot phosphoric acid. (FIG. 22)

Next, wet etching is used to remove the first SiO layer 202 exposing device regions 21 and 22 of the Si substrate surface. (FIG. 23)

Hereafter, in the samemanner as with the first embodiment, the Si substrate surface of these exposed device regions 21 and 22 is subjected to a predetermined amount of oxidation forming a sacrificial oxidized layer (not shown in the FIGS.), and after this sacrificial oxidized layer is removed, the desired devices are formed and interconnected in these device regions 21 and 22 using device formation methods and wiring methods, respectively, familiar to those skilled in the art, so that the semiconductor device formation can be completed. Therefore, respective descriptions of these methods are omitted.

With this embodiment, after etching off the predetermined amount (normally 10 to 50 nm) of the isolation trench formation regions of Si substrate 201, which have been exposed in pad layer hole formation step S202, by configuring side wall layers 205 on the innerwalls of openings 211, 212, and 213, to form isolation trenches 11, 12, and 13, while continuing to keep the precision of the size of device regions 21 and 22 from declining, it is also possible to keep in check the electric current leakage (hump characteristics) at the ends of device regions 21 and 22. The functional result will now be further described while referencing the FIGS.

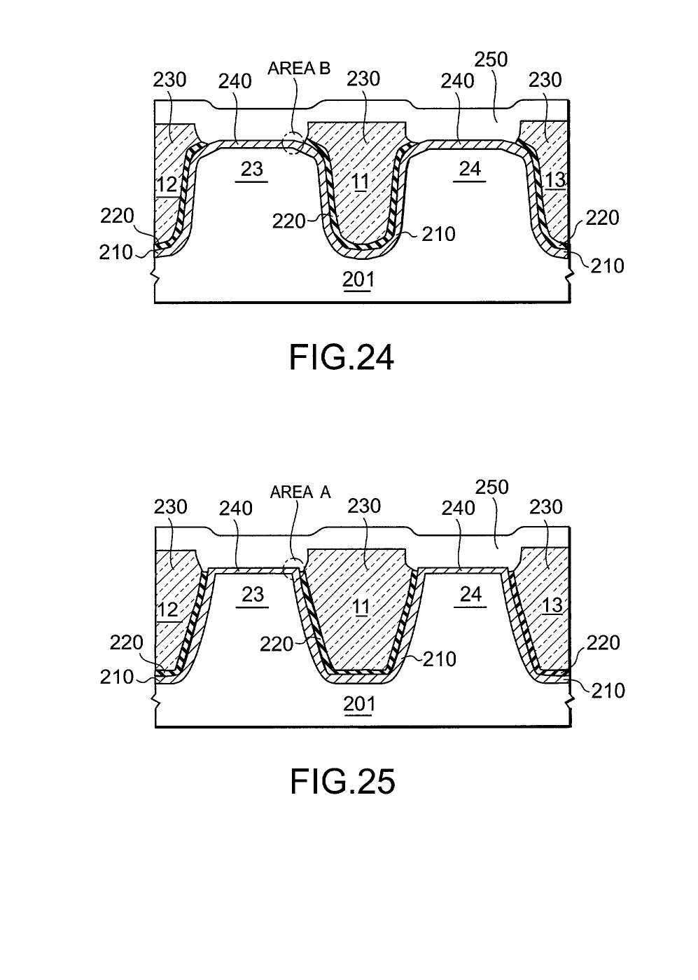

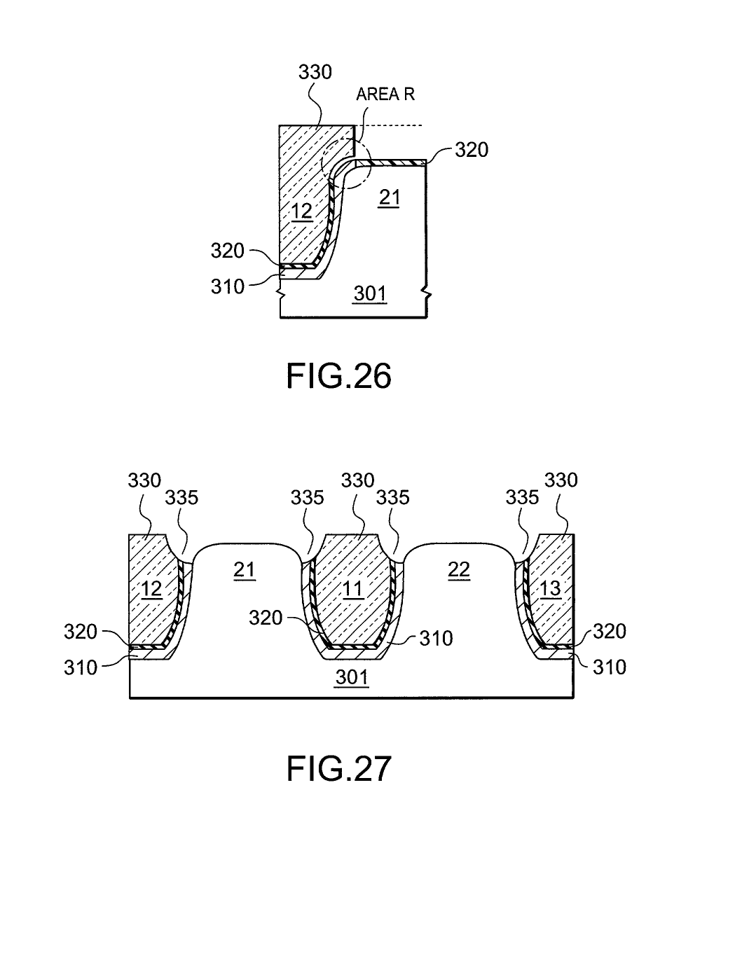

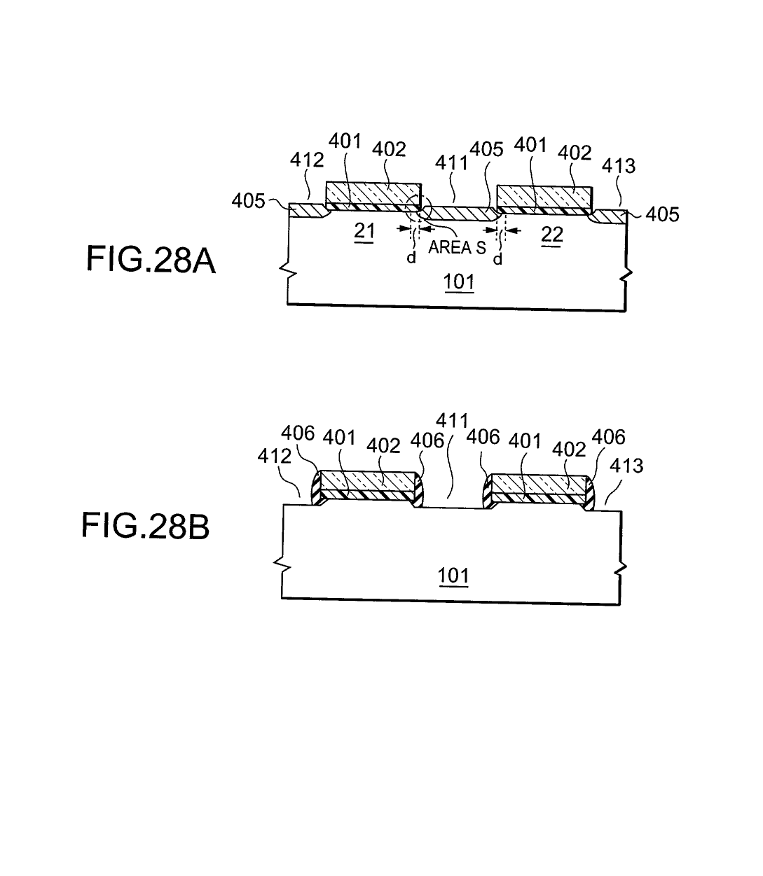

FIGS. 24 and 25 are layered cross-sectional views cut along line Y to Y′ of FIG. 2, up until after the fifth SiO layers 240, which are each gate insulating layers, and gate electrodes 250 have been formed; FIG. 24 shows the STI structure that has been formed using the method in this embodiment, and FIG. 25 shows the STI structure that has been formed without being subjected to first substrate etching step S203.

Comparing FIG. 24 and FIG. 25, when the STI structure is formed using the method in this embodiment, the ends of device regions 21 and 22 near isolation trenches 11, 12 and 13 contain slightly slanted such as with area B; however, when the STI structure is formed without being subjected to the first substrate etching step S203, the slant at the ends is quite sharp such as with area A. As a result, when over etching occurs in the second SiN layer 220 or the third SiO layer 210, the effect on the gate electrode formed in this over etching area is substantially lessened in the case shown in FIG. 24 compared to the case shown in FIG. 25, and forming the STI structure using the method in this embodiment results in the electric current leakage at the ends of device regions 21 and 22 being kept under control.

Furthermore, with this embodiment, in the same manner as the first embodiment, it is possible to limit the occurrence of defects in active zones due to heat treatments during later steps such as activation treatments like gate oxidization and ion doping, it is also possible to control the over etching of the second SiN layer in the upper end of the isolation trenches when removing the first SiN layer using wet etching.

Moreover, the present invention is not limited to the first and second embodiments described above; it may include various modifications within the scope of its substance.

For example, the substrate described in the examples is a silicon substrate; however, it may also be an insulating substrate ora silicon-on-insulator (SOI) substrate with at least a silicon surface.

With the method of forming device isolation structures according to the present invention, since development of defects in active zones due to heat treatments performed on the semiconductor substrate during steps after the steps that form the device isolation structure can be restricted, it is possible to reduce characteristic deficiencies in devices corresponding to defects, which results in the improved overall product yield of a semiconductor device.

Furthermore, since over etching of the second SiN layer at the upper edge of the isolation trenches when removing the first SiN layer using wet etching is controlled and indentations in the isolation trenches, which occur at the boundary area with the active zone, can be reduced, later steps, in particular the step of forming gate electrodes can be accomplished with greater ease and the occurrence of deficiencies such as shorts between adjacent gate electrodes due to the over etching of the gate electrode material towards the indentations can be limited.

In addition, even if described with reference to specific there are some indentations when etching off the predetermined amount from the substrate before configuring sidewall layers on the innerwalls of the openings onthe region where the isolation trenches are to be formed, the occurrence of electric current leakage can be minimized.

Although the invention has been embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A method of forming device isolation structures in semiconductor devices, comprising:
a barrier layer formation step of, after forming predetermined isolation trenches in primary surface of a semiconductor substrate, oxidizing those isolation trenches and then on top of them depositing an oxidation stopping layer;
an isolation trench filling step of, after said barrier layer formation step, depositing isolating materials on the primary surface of said substrate, and filling in said isolation trenches; and
an annealing step of performing wet oxidation processing at a temperature higher than the highest temperature in steps after said isolation trench filling step forming said semiconductor devices.

2. The method of forming device isolation structures mentioned in claim 1, wherein said oxidation stopping layer is a silicon nitride layer.

3. The method of forming device isolation structures mentioned in claim 1, wherein said insulating material is silicon nitride, which is deposited using chemical vapor depositing (CVD).

4. The method of forming device isolation structures mentioned in any one of claim 1 and claim 3, wherein process temperature 3 of the annealing step is in the range of 1050° C. to 1200° C.

5. A method of forming device isolation structures in semiconductor devices comprising:
a pad layer forming step of forming on the primary surface of a semiconductor substrate, a first insulating layer and a first oxidation stopping layer in that order from the bottom layer;
a pad layer hole forming step of removing said first oxidation stopping layer and said first insulating layer from isolating trench forming regions to form openings and to expose said substrate;
a first substrate etching step of etching a predetermined amount of said substrate within said openings;
a sidewall forming step of forming sidewall layers on the side wall of said hole after said first substrate etching step; and
a second substrate etching step of, after said sidewall forming step, etching a predetermined amount of said substrate to form isolation trenches.

6. The method of forming device isolation structures mentioned in claim 5, wherein said first insulating layer is an oxidized layer formed by oxidizing a substrate surface and said oxidation stopping layer is a silicon nitride layer.

7. The method of forming device isolation structures mentioned in claim 5, wherein said sidewall layers are silicon nitride layers.

8. The method of forming device isolation structures mentioned in claim 5, wherein the amount of etching in said first substrate in claim 5, wherein the amount of etching in said first substrate etching step is 10 nm to 50 nm.

9. The method of forming device isolation structures mentioned in claim 5, wherein said substrate is a silicon wafer or is an insulator substrate (a SOI substrate) having at least a layer of silicon on its surface.
